(19) United States
(12) Patent Application Publication
(10) Pub. No.: US 2013/0187116 A1
(43) Pub. Date: Jul. 25, 2013

(54) RRAM Device With Free-Forming Conductive Filament(s), and Methods of Making Same

(71) Applicants: Shyue Seng Tan, Singapore (SG); Wei Zhu, Singapore (SG); Tu Pei Chen, Singapore (SG)

(72) Inventors: Shyue Seng Tan, Singapore (SG); Wei Zhu, Singapore (SG); Tu Pei Chen, Singapore (SG)

(73) Assignee: GLOBALFOUNDRIES SINGAPORE PTE LTD, Singapore (SG)

(21) Appl. No.: 13/353,786

(22) Filed: Jan. 19, 2012

(51) Int. Cl. H01L 45/00; H01L 21/8239; B82Y 99/00

(52) U.S. Cl. 257/4; 438/104; 257/E45.003; 257/E21.004; 257/E21.645; 977/943

(57) ABSTRACT

Disclosed herein is an RRAM device with free-forming conductive filament(s), and various methods of making such an RRAM device. In one example, a device disclosed herein includes a first electrode, a second electrode positioned above the first electrode and a variable resistance material positioned between the first and second electrodes, wherein the variable resistance material is a metal oxide with a plurality of metal nano-crystals embedded therein.

### BACKGROUND OF THE INVENTION

1. Field of the Invention

Generally, the present disclosure relates to sophisticated semiconductor devices and the manufacturing of such devices, and, more specifically, to an RRAM (Resistance Random Access Memory) device with free-forming conductive filament(s), and various methods of making such an RRAM device.

2. Description of the Related Art

As is well known to those skilled in the art, non-volatile memory (NVM) devices are characterized in that there is no loss of data stored in their memory cells, even when an external power supply is removed. For that reason, such non-volatile memory devices are widely employed in computers, mobile communication systems, memory cards and the like.

Flash memory structures are widely used in such non-volatile memory applications. The typical flash memory device employs memory cells having a stacked gate structure. The stacked gate structure typically includes a tunnel oxide layer, a floating gate, an inter-gate dielectric layer and a control gate electrode, which are sequentially stacked above a channel region. While flash memory structures have enjoyed enormous success, the continued and ever-present drive to reduce the size of integrated circuit products has created many challenges for the continued scaling of flash memory devices. Such challenges include scaling of program/erase voltages, access speed, reliability, the number of charges stored per floating gate, etc.

A resistance random access memory (RRAM) device is a simple two-terminal device memory device comprised of two spaced-apart electrodes with a variable resistance material layer or ion conductor layer positioned between the two electrodes. The variable resistance material layer is typically comprised of various metal oxides, such as nickel oxide, titanium oxide, zirconium oxide, copper oxide, aluminum oxide, etc. The variable resistance material layer is used as a data storage layer. The resistance of the variable resistance material layer may be varied or changed based upon the polarity and/or amplitude of an applied electric pulse. The electric field strength or electric current density from the pulse, or pulses, is sufficient to switch the physical state of the materials so as to modify the properties of the material and establish a highly localized conductive filament (CF) in the variable resistance material. The pulse is of low enough energy so as not to destroy, or significantly damage, the material. Multiple pulses may be applied to the material to produce incremental changes in properties of the material. One of the properties that can be changed is the resistance of the material. The change may be at least partially reversible using pulses of opposite polarity or pulses having a different amplitude from those used to induce the initial change.

In general, after an RRAM device is initially fabricated, the variable resistance material layer does not exhibit any switching properties. Rather, a so-called FORMING process, a high-voltage, high-current process, is performed to initially form the localized conductive filament with oxygen vacancies from the cathode, establishing a low-resistance state (LRS) exhibiting a relatively high current flow. A so-called RESET process is performed to break the conductive filament and establish a high-resistance state (HRS) exhibiting a relatively low current flow. This RESET process is typically a current-driven thermal process that causes the conductive filament to be broken by a heat-assisted chemical reaction. More specifically, the conductive filament is broken due to the fact that a high current is passing through an ultra-thin (a few nanometers) conductive filament causing a high current density which leads to high temperatures and a melting down of the conductive filament. Note that the RESET process removes only a portion of the entire length of the conductive filament, i.e., the RESET process does not remove the entire conductive filament. After a RESET process is performed, a so-called SET process is performed to reestablish the conductive filament and thus the low-resistance state of the RRAM device. The SET process is essentially the same as the FORMING process except that the SET process is performed at a lower voltage than the FORMING process since the filament length to be reestablished is shorter than the length of the conductive filament that was formed during the FORMING process.

One problem associated with an RRAM device is the relatively high power required to initially form the localized conductive filament in the variable resistance material layer during the FORMING process. For example, in some current-day RRAM devices, it may take up to approximately 0.2 W of power to initially form the conductive filament. Such a large power requirement for forming the conductive filament is not only wasteful, it is highly incompatible with the scaling of semiconductor devices, such as those employing CMOS technology, and particularly in mobile applications, such as cell phones and the like, where power conservation and battery life is a very important consideration. It is believed that this requirement of a relatively high power to form the conductive filament in an RRAM device has limited the widespread adoption of RRAM devices in integrated circuit products.

The present disclosure is directed to a novel RRAM device with free-forming conductive filament(s), and various methods of making such an RRAM device.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to an RRAM (Resistance Random Access Memory) device with free-forming conductive filament(s), and various methods of making such an RRAM device. In one example, a device disclosed herein includes a first electrode, a second electrode positioned above the first electrode and a variable resistance material positioned between the first and second electrodes, wherein the variable resistance material is a metal oxide-metal nano-crystral containing material.

In another example, a method disclosed herein includes forming a layer of a bottom electrode material, performing a process operation to form a variable resistance material above the layer of bottom electrode material, wherein the variable resistance material layer is a metal oxide-metal nano-crystral containing material, and forming a top electrode material above the layer of variable resistance material.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1F depict one illustrative process flow for forming one illustrative embodiment of a novel RRAM device disclosed herein;

FIGS. 2A-2D depict another illustrative process flow for forming yet another illustrative embodiment of a novel RRAM device disclosed herein; and

FIGS. 3A-3D depict various operational characteristics of the novel RRAM device disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to an RRAM (Resistance Random Access Memory) device with free-forming conductive filament(s), and various methods of making such an RRAM device. As will be readily apparent to those skilled in the art upon a complete reading of the present application, the device disclosed herein may be employed with a variety of technologies, e.g., NMOS, PMOS, CMOS, etc., and it may be incorporated into a variety of integrated circuit products. With reference to the attached drawings, various illustrative embodiments of the methods and devices disclosed herein will now be described in more detail. It should be understood that the various features and layers in the attached drawings may not be to scale so as to facilitate disclosure of the present inventions.

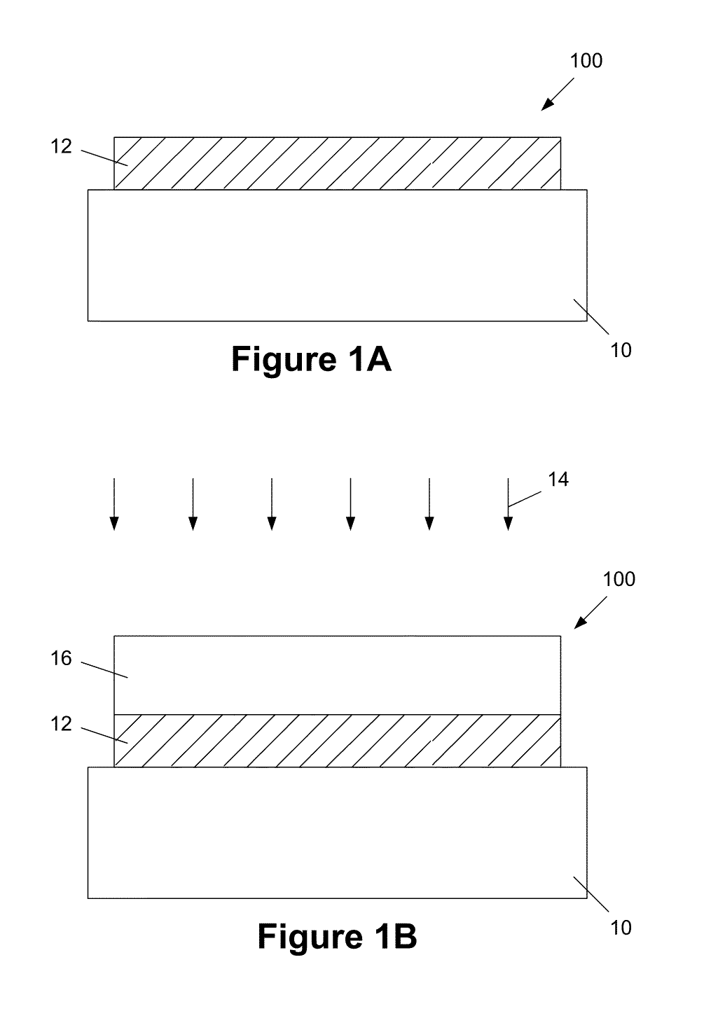

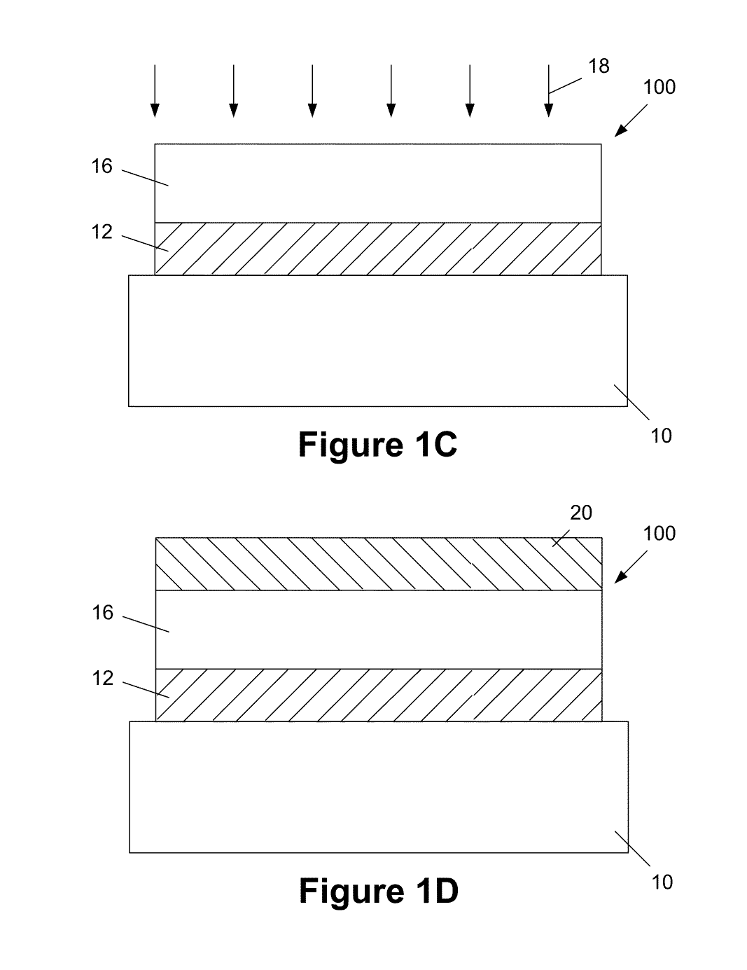

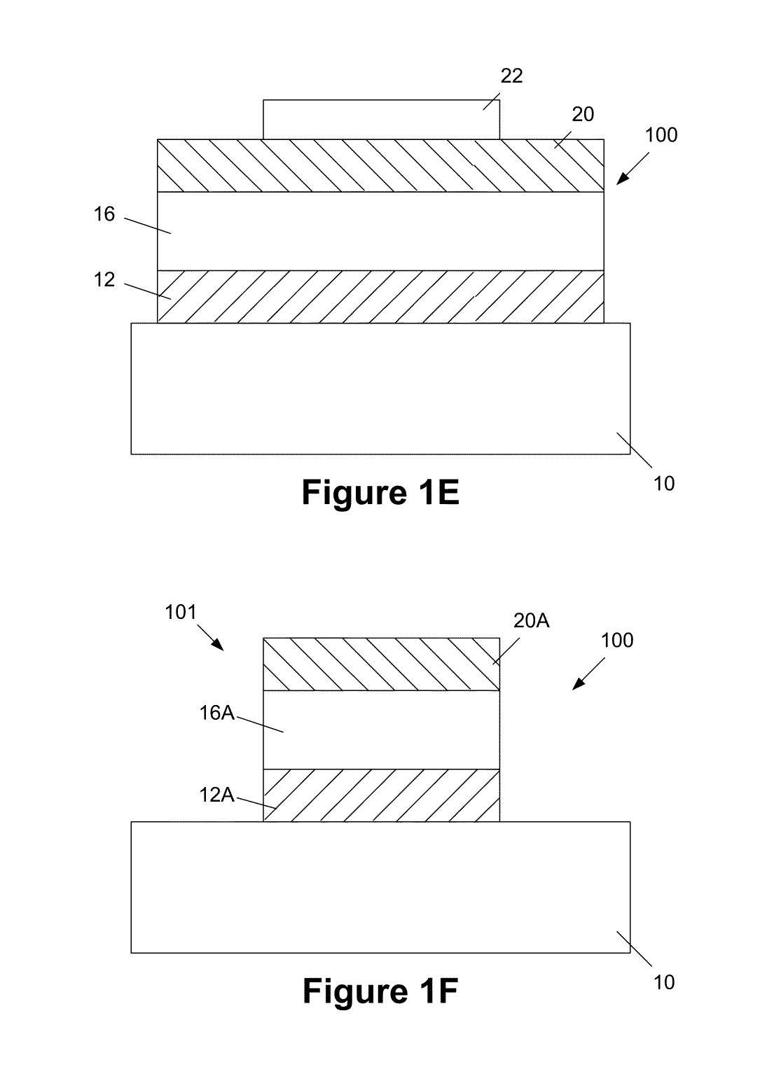

FIGS. 1A-1F depict one illustrative process flow for forming one illustrative embodiment of a novel RRAM device 100 disclosed herein. FIG. 1A is a simplified view of one illustrative embodiment of a novel RRAM device 100 disclosed herein at an early stage of manufacturing. The RRAM device 100 is formed above a semiconducting substrate 10. The substrate 10 may have a variety of configurations, such as the depicted bulk silicon configuration. The substrate 10 may also have a silicon-on-insulator (SOI) configuration that includes a bulk silicon layer, a buried insulation layer and an active layer, wherein semiconductor devices are formed in and above the active layer. Thus, the terms substrate or semiconductor substrate should be understood to cover all semiconductor structures. The substrate 10 may also be made of materials other than silicon. The substrate 10 may be doped with an N-type dopant or a P-type dopant or it may be un-doped. In the illustrative examples depicted herein, the substrate 10 is presumed to be doped with an illustrative P-type dopant such as boron.

FIG. 1A depicts the RRAM device 100 after a bottom electrode material layer 12 has been formed above the substrate 10. In some cases, a layer of insulating material (not shown) may be formed between the bottom electrode material layer 12 and the substrate 10. The bottom electrode material layer 12 may be comprised of a variety of different conductive materials, such as aluminum, tungsten, silicon, platinum, titanium, titanium nitride, copper, gold, etc., and its thickness may vary depending upon the particular application, e.g., 50-1000 nm. The bottom electrode material layer 12 may be formed by performing a variety of deposition processes, such as a physical vapor deposition (PVD) process, a chemical vapor deposition (CVD) process, an atomic layer deposition (ALD) process, or plasma-enhanced versions of those processes, as well as by an electroplating or electroless deposition process, etc. In one illustrative embodiment, the bottom electrode material layer 12 may be a layer of aluminum that was formed by performing a PVD process using an aluminum target.

Next, as shown in FIG. 1B, a deposition process 14 was performed to form a layer of variable resistance material 16 above the bottom electrode material layer 12. In general, the variable resistance material layer 16 may be comprised of a metal oxide-metal nano-crystal material, e.g., an aluminum oxide layer of material that contains aluminum nano-crystals. The layer of variable resistance material 16 may be formed by a variety of techniques and its thickness may vary depending upon the particular application, e.g., 20-100 nm. In one illustrative embodiment, the layer of variable resistance material 16 may be a layer of aluminum oxide-aluminum nano-crystals material having a thickness of about 60 nm that was formed by performing an RF magnetron sputtering process using an aluminum target. The RF sputtering process was performed in an oxygen ambient at a power of about 310 W, with an RF frequency of 13.6 MHz. During the process, the argon (Ar) to oxygen ratio was set to be about 60:1. In other illustrative embodiments, the layer of variable resistance material 16 may be a layer of nickel rich-nickel oxide material, titanium rich-titanium oxide material, zirconium rich-zirconium oxide material, copper rich-copper oxide material, hafnium rich-hafnium oxide material, etc. In some cases, the metal nano-crystal may be of the same metal as the metal oxide material, e.g., aluminum oxide-aluminum nano-crystals, nickel oxide-nickel nano-crystals, etc. In other cases, the nano-crystals may be made of a different metal than the metal present in the metal oxide layer, e.g., aluminum nano-crystals in a layer of hafnium oxide. Thus, the present invention should not be considered as limited to any particular metal oxide-metal nano-crystal combination.

Next, as shown in FIG. 1C, a heating process 18 was performed on the layer of variable resistance material 16. In one illustrative embodiment, the heating process 18 may be a rapid thermal anneal process performed at a temperature of about 500-1000° C. for a duration ranging from about 30 seconds-5 minutes, depending on the particular application.

FIG. 1D depicts the RRAM device 100 after a top electrode material layer 20 has been formed above the layer of variable resistance material 16. The top electrode material layer 20 may be comprised of the same materials and formed using the same illustrative techniques as those identified above for the bottom electrode material layer 12. The thickness of the top electrode material layer 20 may vary depending upon the particular application, e.g., 50-100 nm. In some cases, the top electrode material layer 20 and the bottom electrode material layer 12 may be made of the same material, although that is not required in all applications. In one illustrative embodiment, the top electrode material layer 20 may be a layer of aluminum that was formed by performing a PVD process using an aluminum target.

In FIGS. 1E-1F, traditionally photolithography and etching processes are performed to pattern the top electrode material layer 20, the layer of variable resistance material 16 and the bottom electrode material layer 12 to define the basic material stack 101 (see FIG. 1F) for this illustrative embodiment of the RRAM device 100. More specifically, with reference to FIG. 1E, a patterned mask layer 22, e.g., a photoresist mask, is formed above the top electrode material layer 20. Thereafter, one or more etching processes are performed through the patterned mask layer 22 to define the material stack 101 of the RRAM device 100 shown in FIG. 1F. As shown therein, in this embodiment, the RRAM device 100 has a basic metal-insulator-metal (MIM) configuration comprised of a bottom electrode 12A, a variable resistance material 16A and a top electrode 20A. As shown in FIG. 1F, the patterned mask layer 22 was removed after patterning the various layers of materials. It should also be noted, that, as mentioned above, the RRAM device 100 may also have a metal-insulator-silicon (MIS) configuration when the bottom electrode is comprised of silicon.

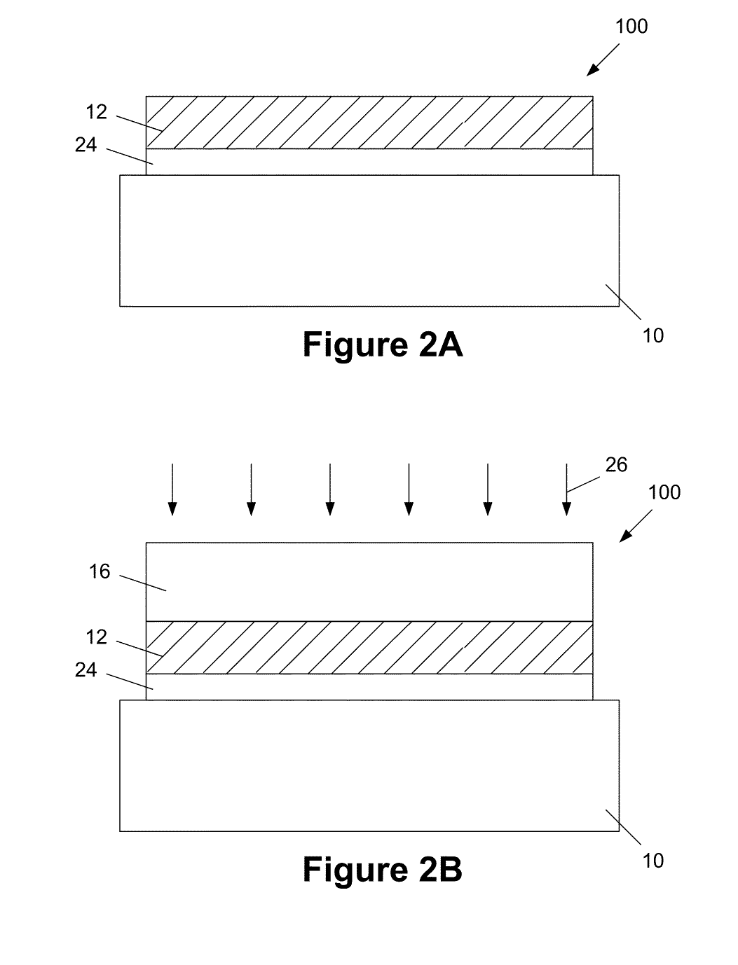

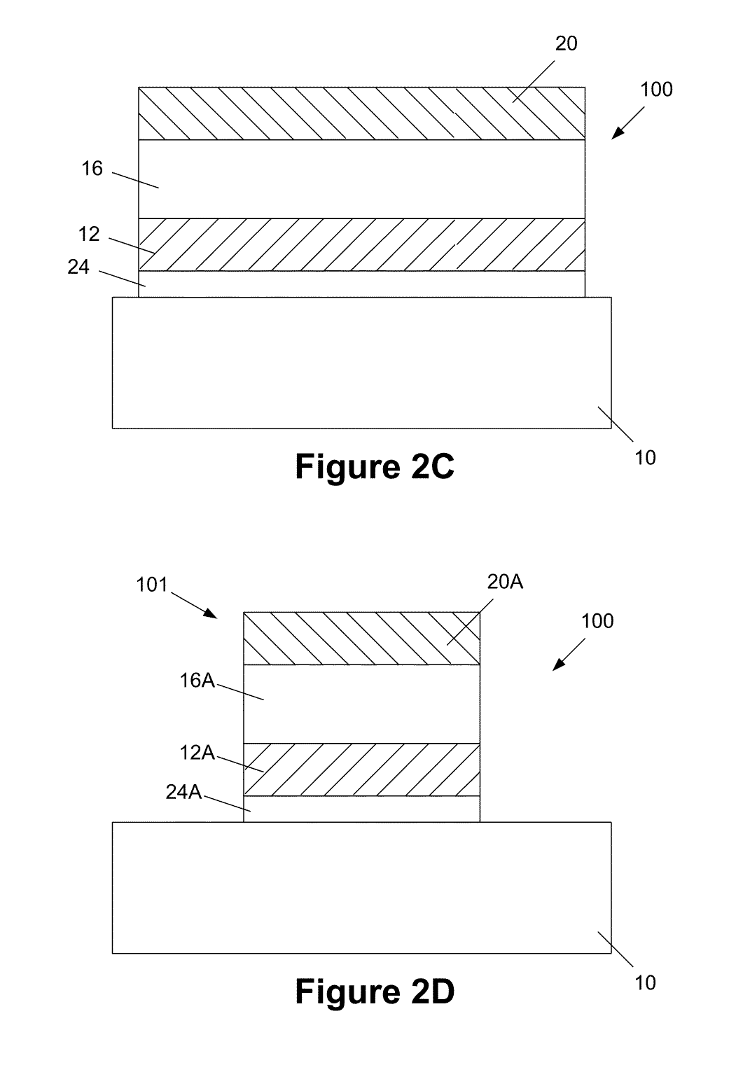

FIGS. 2A-2D depict another illustrative process flow for forming one illustrative embodiment of the novel RRAM device 100 disclosed herein. FIG. 2A is a simplified view of the illustrative RRAM device 100 disclosed herein at an early stage of manufacturing that is formed above the semiconducting substrate 10. As shown in FIG. 2A, a layer of insulating material 24 is formed above the substrate 10. The layer of insulating material 24 may be comprised of a variety of different materials, such as, for example, silicon dioxide, a so-called high-k (k greater than 10) insulation material, etc., it may be formed by a variety of process techniques, CVD, a thermal growth process, etc., and it may have a thickness within the range of about 10-1000 nm. Thereafter, the bottom electrode material layer 12 described above may be deposited above the layer of insulating material 24. Using the techniques disclosed in FIG. 2A-2D, in one illustrative example, the bottom electrode material layer 12 may be comprised of aluminum and it may have a thickness of about 100-5000 nm.

Next, as shown in FIG. 2B, an anodization process 26 was performed on the bottom electrode material layer 12 to form the layer of variable resistance material 16 described above. In one illustrative example where the bottom electrode material layer 12 is comprised of aluminum, the process 26 was performed using 0.15 ml of oxalic acid at a temperature of about 25° C. for a duration of about 120 minutes. The process 26 was performed at a substantially constant voltage of about 40V employed using a Keithley™ 2400 source meter.

A 2×2 cm² platinum mesh was used as the cathode during the process 26. In FIG. 2C, the top electrode material layer 20 has been formed above the layer of variable resistance material 16 using the materials and techniques described previously.

FIG. 2D reflects the RRAM device 100 after traditionally photolithography and etching processes (similar to those described above with respect to FIGS. 1E-1F) have been performed to pattern the various layers of material depicted in FIG. 2C. As shown in FIG. 2D, the patterning processes result in the definition of the basic material stack 101 for this illustrative embodiment of the RRAM device 100. In this case, the basic material stack 101 is positioned above the patterned layer of insulating material 24. As shown in FIG. 2D, in this embodiment, the RRAM device 100 has a basic metal-insulator-metal (MIM) configuration comprised of a bottom electrode 12A, a variable resistance material 16A and a top electrode 20A. It should also be noted that, as mentioned above, the RRAM device 100 may also have a metal-insulator-silicon (MIS) configuration, wherein, in this illustrative process flow, the bottom electrode is comprised of silicon.

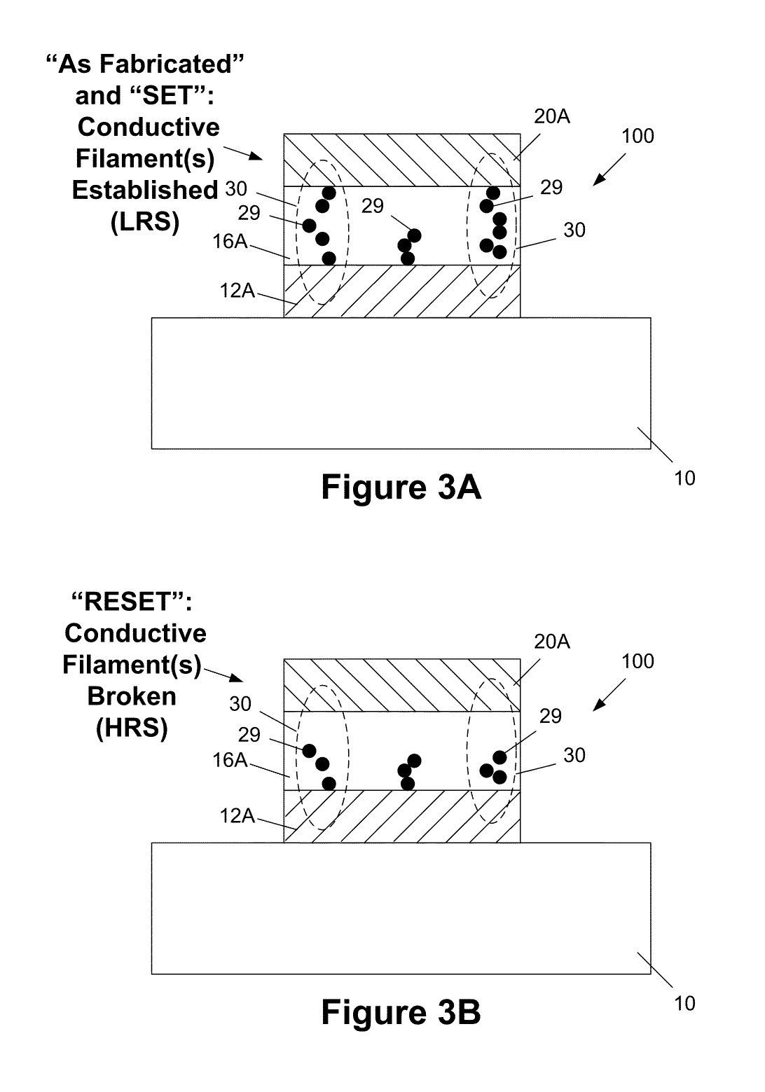

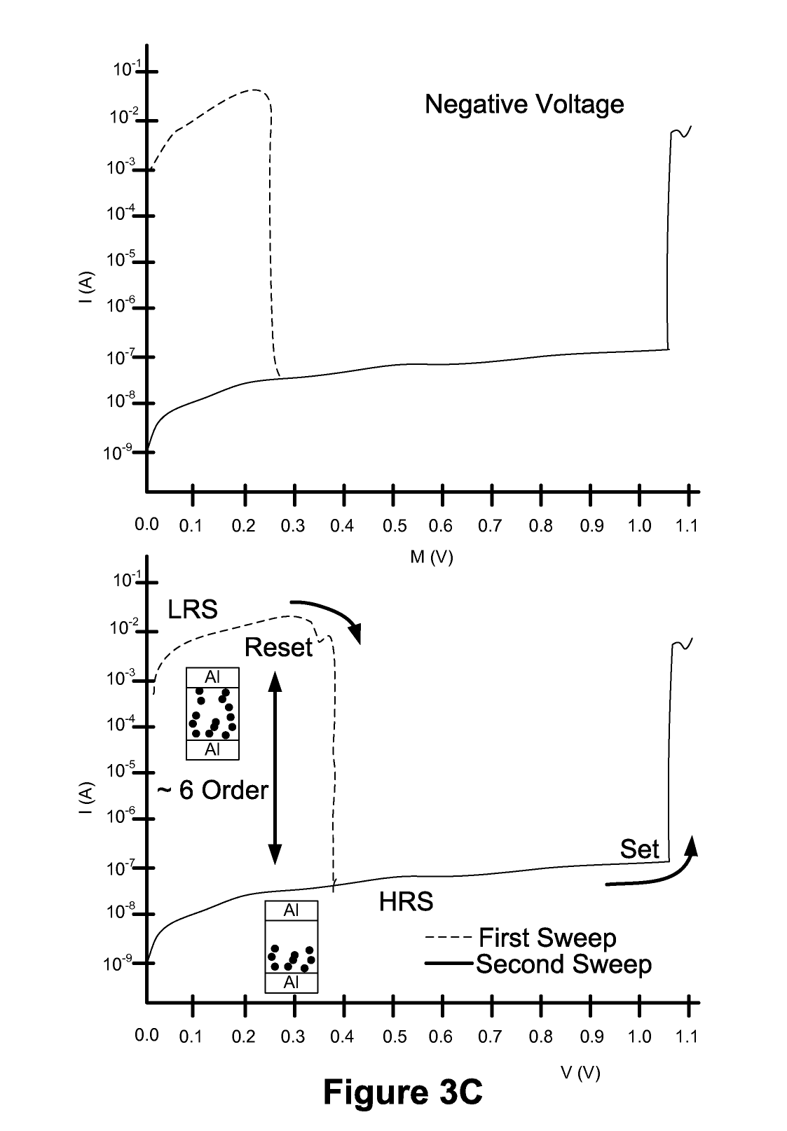

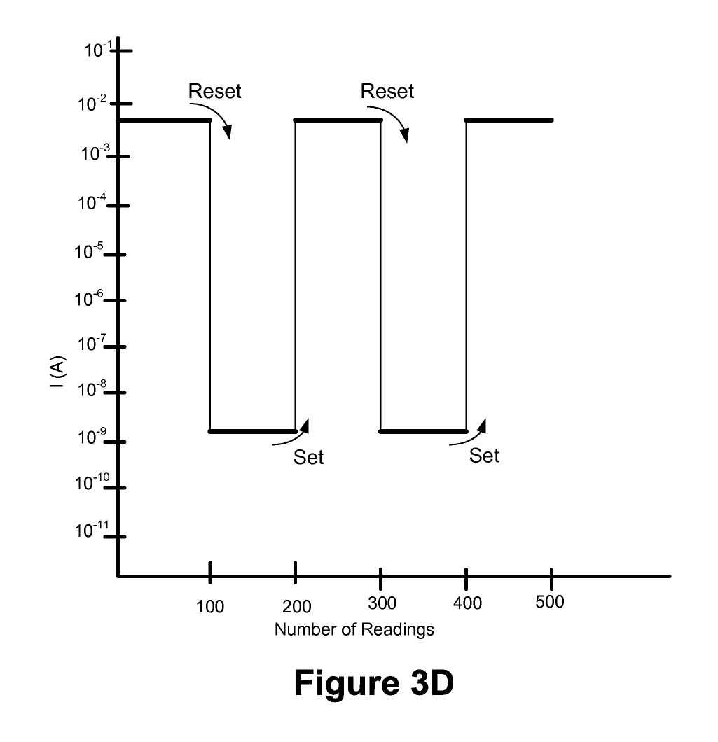

FIGS. 3A-3B will be referenced to explain various operational characteristics of the novel RRAM device 100 disclosed herein. With reference to FIG. 3A, after the layer of variable resistance material 16A is fabricated using the methods disclosed, the layer of variable resistance material 16A is comprised of a plurality of schematically depicted metal nano-crystals 29 embedded in the layer of variable resistance material 16A (e.g., a metal oxide). The metal nano-crystals 29 form a plurality of conductive filaments 30 that establish a low-resistance state (LRS) between the bottom and top electrodes 12A, 20A. Importantly, the conductive filaments 30 are established without having to perform the relatively high-voltage, high-temperature FORMING process described in the background section of this application. Thus, FIG. 3A schematically depicts the RRAM device disclosed herein in both the “AS FABRICATED” condition as well as a representative SET condition. In addition, even without performing the traditional FORMING step, the RRAM device disclosed herein can be changed from a low-resistance state (LRS) to a high-resistance state (HRS) (or vice-versa) using the same SET/RESET processes as described in the background section of this application. Additionally, with the formation of multiple conductive filaments 30 using the methods disclosed herein, instead of the formation of the highly-localized conductive filament in prior art RRAM devices, the novel RRAM device 100 exhibits improved reliability and better characteristics for use as a memory device.

FIGS. 3C-3D will be referenced to describe further characteristics and performance aspects of the RRAM device 100 disclosed herein. FIG. 3C demonstrates that, as initially formed, the RRAM device 100 exhibits a relatively low-resistance state (LRS) wherein a current a little greater than 10⁻³ amps is established almost immediately upon application of a voltage to the RRAM device 100, and this current may be as high as about 10⁻² amp for voltages up to about 0.3 V. At that point, the RESET process is performed at about 0.4 V to destroy portions of the conductive filaments 30, thereby making the RRAM device 100 exhibit a relatively high-resistance state (HRS) with a greatly reduced current flow of about 10⁻⁸ amps. After the device is in its high-resistance state, a SET process may be performed wherein a voltage of a little more than 1 V is applied to the device 100 to reestablish the conductive filaments 30 such that the RRAM device 100 is in its low-resistance state (LRS). Accordingly, in one illustrative embodiment, the RRAM device 100 disclosed herein exhibits a relatively large difference in current flow for the device when it is in its low-resistance state (about 10⁻² amps) as compared to when it is in its high-resistance state (about 10⁻⁸ amps), i.e., about a 6 times order of magnitude difference. In contrast, a typical prior art RRAM device normally exhibited a difference of about 1-4 orders of magnitude (LRS v. HRS). The relatively large difference in the current flow of the device 100 between the two states (LRS v. HRS) makes sensing the state of the RRAM device 100 disclosed herein easier and more useful in a memory application. The sensing circuitry need not be as complex or sensitive as sensing circuitry employed with prior art RRAM devices. The insert graph in FIG. 3C establishes that the device 100 can operate in a bipolar fashion with negative voltages applied to the RRAM device 100 to cause it to change from a low-resistance state to a high-resistance state. FIG. 3D depicts the reliability and stability of the RRAM device 100 disclosed herein.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. An RRAM device, comprising:
a first electrode;
a second electrode positioned above said first electrode; and
a variable resistance material positioned between said first and second electrodes, wherein said variable resistance material is a metal oxide-metal nano-crystral containing material.

2. The device of claim 1, wherein said first electrode is a bottom electrode that is comprised of at least one of aluminum, tungsten, silicon, platinum, titanium, titanium nitride, copper and gold.

3. The device of claim 1, wherein said second electrode is a top electrode that is comprised of at least one of aluminum, tungsten, silicon, platinum, titanium, titanium nitride, copper and gold.

4. The device of claim 1, wherein said variable resistance material layer is a layer of aluminum oxide that contains aluminum nano-crystals, a layer of nickel oxide that contains nickel nano-crystals, a layer of titanium oxide that contains titanium nano-crystals, a layer of zirconium oxide that contains zirconium nano-crystals, a layer of copper oxide that contains copper nano-crystals or a layer of hafnium oxide that contains aluminum nano-crystals.

5. The device of claim 1, further comprising a layer of insulating material positioned between said first electrode and a semiconducting substrate.

6. The device of claim 1, wherein said first electrode is comprised of aluminum and said variable resistance material is comprised of aluminum oxide with embedded aluminum nano-crystals.

7. The device of claim 1, wherein at least some of said embedded metal nano-crystals establish at least one conductive filament between said first and second electrodes.

8. The device of claim 7, wherein said embedded metal nano-crystals establish a plurality of conductive filaments between said first and second electrodes.

9. An RRAM device, comprising:
a bottom electrode comprised of aluminum;
a top electrode comprised of aluminum positioned above said bottom electrode; and
a variable resistance material positioned between said bottom and top electrodes, wherein said variable resistance material is an aluminum oxide material that contains aluminum nano-crystals.

10. The device of claim 9, further comprising a layer of insulating material positioned between said bottom electrode and a semiconducting substrate.

11. A method of forming an RRAM device, comprising:
forming a layer of a bottom electrode material;
performing a process operation to form a variable resistance material layer above said layer of bottom electrode material, wherein said variable resistance material layer is a metal oxide-metal nano-crystral containing material; and
forming a top electrode material above said layer of variable resistance material.

12. The method of claim 11, wherein performing said process operation to form said variable resistance material layer comprises performing an RF plasma based magnetron sputtering process using a metal target to initially form said variable resistance material layer above said bottom electrode material.

13. The method of claim 12, further comprising performing a heating process at a temperature within the range of about 500-1000° C. on said variable resistance material layer.

14. The method of claim 11, wherein performing said process operation to form said variable resistance material layer comprises performing an anodization process on said bottom electrode material layer to form said variable resistance material layer.

15. The method of claim 14, wherein said variable resistance material layer is comprised of aluminum and wherein performing said anodization process comprises exposing said bottom electrode material layer to approximately 0.15 ml of oxalic acid at a temperature of about 25° C. for a duration of about 120 minutes.

16. The method of claim 14, wherein said bottom electrode is comprised of aluminum and said variable resistance material is an aluminum oxide material that contains a plurality of aluminum nano-crystals.

17. A method of forming an RRAM device, comprising:
forming a layer of a bottom electrode material;
performing an RF plasma based magnetron sputtering process using a metal target to initially form a variable resistance material layer above said layer of bottom electrode material, wherein said variable resistance material layer is a metal oxide-metal nano-crystal containing material;
performing a heating process at a temperature of at least about 500° C. on said variable resistance material layer; and
forming a top electrode material above said variable resistance material layer.

18. The method of claim 17, wherein said bottom electrode is comprised of aluminum and said variable resistance material is an aluminum oxide material that contains a plurality of aluminum nano-crystals.

19. A method of forming an RRAM device, comprising:
forming a layer of a bottom electrode material;
performing an anodization process on said layer of bottom electrode material to form a variable resistance material layer above said layer of bottom electrode material, wherein said variable resistance material layer is a metal oxide-metal nano-crystal containing material; and
forming a top electrode material above said variable resistance material layer.

20. The method of claim 19, wherein said bottom electrode is comprised of aluminum and said variable resistance material is an aluminum oxide material that contains a plurality of aluminum nano-crystals.
